(19) United States
(12) Patent Application Publication
(10) Pub. No.: US 2026/0319388 A1
(43) Pub. Date: Oct. 15, 2026

(54) CONNECTION OF A HOLDING ELEMENT TO AN OPTICAL ELEMENT VIA A CONNECTING MATERIAL

(71) Applicant: Carl Zeiss SMT GmbH, Oberkochen (DE)

(72) Inventors: Rusbeh GOECKE, Aalen (DE); Hansjochen KOECKERT, Aalen (DE); Dirk SCHAFFER, Jena (DE); Joachim HARTJES, Aalen (DE); Wolfgang SCHERM, Nattheim (DE); Franz SORG, Aalen (DE); Tristan SCHLOTTHAUER, Gaildorf-Eutendorf (DE)

(21) Appl. No.: 19/692,638

(22) Filed: May 29, 2026

Related U.S. Application Data
(63) Continuation of application No. PCT/EP2024/084788, filed on Dec. 5, 2024.

(30) Foreign Application Priority Data
Dec. 5, 2023 (DE) 10 2023 212 210.3

(51) Int. Cl. G03F 7/00; G02B 7/02

(52) U.S. Cl. CPC G03F 7/70825; G02B 7/025; G03F 7/7095

(57) ABSTRACT

A method connects a holding element to an, for example rotationally symmetrical, optical element via a connecting material. The method comprises: arranging the connecting material between the holding element and the optical element; and curing the connecting material, wherein the connecting material is irradiated with a radiation for curing the connecting material.

### CROSS-REFERENCE TO RELATED APPLICATIONS

The present application is a continuation of, and claims benefit under 35 USC 120 to, international application No. PCT/EP2024/084788, filed Dec. 5, 2024, which claims benefit under 35 USC 119 of German Application No. 10 2023 212 210.3, filed Dec. 5, 2023. The entire disclosure of each of these applications is incorporated by reference herein.

### FIELD

The disclosure relates to a method for connecting a holding element to an optical element via a connecting material, comprising: arranging the bonding material between the holding element and the optical element; and curing the bonding material, wherein the bonding material is irradiated with a radiation for curing the bonding material. The disclosure also relates to a holding element for connection to an optical element via a connecting material and to a system for connecting a holding element to an optical element via a connecting material, such as for carrying out the method according to the disclosure.

### BACKGROUND

It is known to insert lenses into mounts and bond them with the aid of adhesives. Generic optical assemblies are used, for example, in lighting systems and projection lenses for structuring and process control in microlithography. The use of adhesives that can be cured using UV light has proven to be particularly advantageous for a permanent bond.

In known methods, UV adhesive can be applied through injection channels between the lens and the frame at the intended bonding points and irradiated for curing with the help of a UV light source. For this purpose, the UV light source can be manually aligned to the bonding points so that they are directly irradiated by imaging the focus of the UV light source through the upper optical surface of the lens onto the edge cylinder of the lens. Different lens geometries can accept different angles of incidence in order to introduce the light into the bonding gap. Convex optical surfaces can be particularly poorly suited for coupling light for adhesive activation, as total reflection of the excitation radiation can be more likely on convex surfaces. Known methods can limit the implementation of optical designs.

In combination with position and angle deviations of the UV light source due to manual positioning, this can also result in strong fluctuations in the intensity and dose of the irradiation, which in turn has an influence on the reliable curing of the adhesive. This can result in a risk of fluctuations in the strength of the adhesive, which can lead to position drifts of the lens. Known methods can entail an increased process risk.

### SUMMARY

The present disclosure seeks to provide a method for connecting a holding element to an optical element via a connecting material, which can address certain disadvantages associated with known methods. For example, a method is to be provided with which a holding element can be connected to an optical element in a process-reliable manner, which can help allow relatively flexible optical designs and which can be relatively cost-effective. The disclosure also seeks to provide a holding element for connection to an optical element via a connecting material and a system for connecting a holding element to an optical element via a connecting material, such as for carrying out the method according to the disclosure.

According to a first aspect, the disclosure provides a method for connecting a holding element to an optical element via a connecting material, comprising the steps of: arranging the connecting material between the retaining element and the optical element; and curing the connecting material, the connecting material being irradiated with radiation for curing the connecting material, wherein the radiation for curing the connecting material is coupled into the connecting material via a deflecting device for deflecting the radiation. The method can be suitable for materially bonding a retaining element to an optical element. The method can be used to achieve a permanent connection between the holding element and the optical element. The method can be used for example for manufacturing an optical assembly comprising a holding element and an optical element connected to the holding element. The optical assembly can be suitable for use in a microlithography system, for example in an exposure and/or projection system of a microlithography system.

The holding element can be suitable for connection to the optical element. The holding element can be a holding element for microlithography. The holding element can be, for example, a mount, such as a lens mount. The holding element can, for example, be a socket, such as a mirror socket for connection to a mirror. With the aid of the holding element, it is possible for example to arrange the optical element in an optical system, for example a projection system of a projection exposure system for microlithography. For example, the holding element can be used to position the optical element, for example on an optical axis of the optical system. The material of the holding element comprises, for example, metal and/or ceramic. In the case of a bushing, such as a mirror bushing for connection to a mirror, the bushing can be metallic. Furthermore, the bushing can form a defined interface between a support structure, an actuator and a mirror substrate. The bushing can serve the purpose of distributing the weight and operating forces with the aim of low deformation and stress reduction. Furthermore, the bushing can serve the purpose of decoupling parasitic forces and torques, serve as a production interface and/or ensure that the interface is interchangeable in general.

The optical element can be an optical element for microlithography. For example, the optical element can be an at least partially transparent optical element. The optical element can comprise, for example, a transparent substrate. For example, the substrate of the optical element can comprise a material that is transparent to radiation from a spectral range suitable for curing the connecting material. For example, the substrate of the optical element can transmit in the ultraviolet spectral range. For this purpose, the substrate of the optical element can comprise a material that is transparent to wavelengths in the ultraviolet spectral range. For example, the substrate may comprise fused silica, calcium fluoride, magnesium fluoride, barium fluoride, strontium fluoride, germanium dioxide glass and/or any other type of glass, for example FK5, LLF1 or LF5. The material that can be used can depend, for example, on the useful wavelength of the system, such as a projection exposure system, in which the optical element is used. The optical element can be a lens, for example a lens with at least one convex and/or concave optical surface. It is also conceivable that the optical element is a flat plate, a mirror, a mangin mirror or a transmitting diffractive optical element. For example, the optical element in this context can be a mirror with a concave reflective surface. The mirror may have one or more polished areas to allow or enhance entry and/or exit of radiation for curing the bonding material into the substrate of the mirror.

The optical element can be connected to the holding element via a connecting material, such as a hardenable connecting material. The connecting material can be suitable for bonding the optical element to the holding element. The connecting material can be for example an adhesive, such as a radiation-activated adhesive. The adhesive can be cured by ultraviolet light, such as ultraviolet light with a specific spectral distribution. It is conceivable, for example, to use an epoxy resin-based adhesive that can be cured with UV light of the Hg-I line. It is also conceivable that an adhesive is used that is cured with radiation of a different spectral range.

The connecting material can be placed between the holding element and the optical element. The arrangement of the connecting material between the holding element and the optical element can comprise an application of the connecting material to at least one connection point between the holding element and the optical element. The connecting material can, for example, be applied to the holding element and/or to the optical element.

The connecting material can be cured in order to achieve a material bond between the retaining element and the optical element. The cured connecting material can be used for example to achieve a permanent connection between the retaining element and the optical element. For curing, the bonding material is irradiated with radiation to cure the bonding material. The radiation source can be selected depending on its compatibility with the selected bonding material. It is conceivable, for example, that the joining material is irradiated with UV radiation. The UV radiation can be provided by a UV radiation source, such as a UV condenser. It is also conceivable that the joining material is irradiated with radiation from a different spectral range. To cure the bonding material, the radiation can be at least partially coupled into the bonding material.

The radiation for curing the joining material can be coupled into the joining material via a deflector. The deflection device is suitable for deflecting radiation for curing the bonding material. For example, the deflection device can be set up to deflect the radiation for curing the joining material in the direction of the joining material. For example, the deflecting device may be a deflecting element or several interacting deflecting elements. Examples of deflecting elements in this context include reflective elements or light guides. The deflecting device can be used to deflect radiation from a first direction to a second direction for curing the bonding material, for example. The deflecting device can be designed for example so that radiation impinging on the deflecting device and/or radiation coupled into the deflecting device is coupled into the connecting material between the holding element and the optical element via the deflecting device in order to cure the connecting material. The deflection device can, for example, be arranged adjacent to the optical element.

It has been shown that coupling radiation for curing the joining material into the joining material via a deflecting device can allow indirect irradiation of the joining material. Indirect irradiation can be understood to mean that the radiation source is not directed directly onto the joining material, but rather onto the at least one deflecting device, which then directs the radiation in the direction of the joining material. The method can therefore be used to cure the bonding material without having to irradiate the bonding material directly. This can help make it possible to largely decouple the positioning of the radiation source from the design of the optical element. With the aid of the disclosure, it can be possible to uniformly couple radiation into the connecting material independently of the geometry of the optical element. This can be desirable because the geometry of the optical design can follow other higher boundary conditions, which result for example from the desired function of the optical assembly, for example user desired properties for the microlithography system.

According to a second aspect of the present disclosure, the disclosure provides a holding element for connection to an optical element via a connecting material. The holding element comprises at least one deflecting device for deflecting radiation for curing the connecting material. The deflecting device is designed such that radiation impinging on the deflecting device for curing the connecting material is coupled into the connecting material between the holding element and the optical element via the deflecting device. The holding element for connection to an optical element via a connecting material can be suitable for carrying out a method according to the first aspect. The holding element can be suitable for use in a microlithography system, for example in an exposure and/or projection system of a microlithography system.

According to a third aspect of the present disclosure, the disclosure provides a system for connecting a holding element to an optical element via a connecting material, comprising: an optical element; and a holding element for connection to the optical element, wherein the system comprises at least one deflection device for deflecting radiation for curing the connecting material, the deflection device being designed such that radiation impinging on the deflection device for curing the connecting material is coupled into the connecting material between the holding element and the optical element via the deflection device. The system for connecting the holding element to the optical element via the connecting material can be suitable for carrying out the method according to the first aspect. The holding element for connection to the optical element is for example a holding element according to the second aspect.

According to a fourth aspect of the present disclosure, the disclosure provides an optical assembly for microlithography comprising: an optical element; and a holding element, wherein the holding element is connected to the optical element, wherein the optical assembly comprises at least one deflecting device for deflecting radiation for curing the bonding material, wherein the deflecting device is designed such that radiation incident on the deflecting device is coupled into the bonding material between the holding element and the optical element via the deflecting device for curing the bonding material. The optical assembly is manufactured for example according to a method according to the first aspect. For example, the optical assembly comprises a holding element according to the second aspect.

Embodiments of the disclosure are covered by the claims and are explained below.

According to an embodiment of the present disclosure, the radiation for curing the joining material is deflected transversely through the optical element in the direction of the joining material via the deflecting device for deflecting the radiation. For example, the deflection device for deflecting the radiation is set up to deflect the radiation for curing the bonding material transversely through the optical element in the direction of the bonding material. For example, the deflection device can be arranged in such a way that radiation hitting the deflection device is deflected via the deflection device for curing the bonding material in such a way that the radiation is coupled into the optical element and guided in the direction of the bonding material. For example, the optical element can act as a light guide. The radiation can then be guided through the optical element in the direction of the bonding material. For example, the radiation for curing the joining material can be guided through the optical element to a joint to which the joining material is applied. The radiation for curing the joining material can then be at least partially coupled into the joining material in order to cure the joining material. Because the radiation for curing the bonding material is deflected transversely through the optical element via the deflection device, the radiation can be coupled into the bonding material regardless of the shape of the optical element, such as transversely. For example, the radiation can first impinge on a deflecting element of the deflecting device before the radiation enters the optical element, whereby the radiation is deflected transversely through the optical element via the deflecting element, such as in the direction of the connecting material or a further deflecting element. For example, the radiation can be deflected transversely through an optically usable area of the optical element via the deflection element. The optically usable area can be understood as the area through which radiation passes when the optical element is used for its intended purpose.

According to an embodiment of the present disclosure, the optical element has at least one optical surface and one side surface. An optical element generally has a front surface, a rear surface and a side surface. An optical surface can be understood as a surface through which radiation passes during use of the optical element, for example during operation of an optical system comprising the optical element. No radiation usually passes through the side surface of an optical element. Rather, the side surface limits the optical element to the side. A side surface of a rotationally symmetrical optical element, such as a lens, can be understood in particular as the edge cylinder of the optical element. The axis of the edge cylinder of the optical element is usually parallel to the axis of rotation of the optical element. In the case of a lens, the useful radiation first passes through the front surface and then the rear surface, whereby the front surface and the rear surface are designed as optical surfaces. The optical element is connected, such as bonded, to a holding element via the side surface, for example.

The radiation for curing the bonding material can be coupled into the optical element via the side surface of the optical element via the deflection device for deflecting the radiation. For example, the deflection device can be arranged in such a way that the radiation for curing the bonding material is coupled into the optical element via the side surface of the optical element via the deflection device. It is conceivable, for example, that the deflection device is arranged adjacent to the optical element, such as the side surface of the optical element. The fact that the radiation is coupled into the optical element via the side surface of the optical element via the deflection device means that the radiation for curing the bonding material can be coupled into the optical element independently of the shape of the optical surfaces of the optical element. For example, the radiation source can be positioned independently of the geometry of the optical surfaces of the optical element. It has been shown that indirect irradiation can provide more power regardless of the shape of the optical element. For biconvex lenses for example, the same input power of the radiation source can be used to provide around 15 times the power of certain known connection methods. With the aid of the disclosure, additional degrees of freedom can be achieved in the process design or in the optical design. The higher efficiency can help enable a shorter exposure time.

The deflection device can be arranged, for example, at least approximately at a 45°angle to the side surface of the optical element. It is conceivable, for example, that the radiation for curing the joining material is directed at least substantially perpendicular to the side surface of the optical element via the deflection device. For example, the deflection device is aligned at a 45° angle to the line of sight to the joint. The side surface may have a certain roughness. Radiation impinging on the side surface can be scattered randomly, for example. Reflections, such as total reflections, can occur on the optical surfaces in the optical element, so that the optical element acts as a light guide. This can help focus the light on the opposite side of the optical element.

According to an embodiment of the present disclosure, the connecting material is applied to at least one connection point between the holding element and the optical element. For example, the connecting material is applied to the optical element and/or the holding element. It is conceivable, for example, that the connecting material is applied to the surface of at least one connection point, such as to the optical element and/or the holding element. The connecting material can be used to create a material bond at at least one connection point between the optical element and the retaining element. The deflection device for deflecting the radiation for curing the bonding material can be arranged at least substantially opposite the at least one connection point between the holding element and the optical element. This can be desirable for an optical element designed as a lens, as the symmetry results in self-focusing effects, for example a tendency to focus on the opposite bonding means, for example in the opposite bonding gap. Other positions may be more desirable for other optical elements. The deflection device can be arranged on a side of the optical element that is at least substantially opposite the connection point. For example, the deflection device is used to direct radiation for curing the bonding material to an entry point on the optical element which is at least substantially opposite the bonding point.

The connecting material can be applied to a plurality of connection points between the holding element and the optical element. A plurality of connection points means in particular two or more connection points. The connecting material can be applied to at least three connection points between the holding element and the optical element. A deflection device for deflecting the radiation for curing the bonding material can be arranged at least substantially opposite each of the connection points, such as on a substantially opposite side of the optical element. It is conceivable, for example, that the bonding material is applied to six connection points between the holding element and the optical element, with six deflection devices arranged substantially opposite each other. Via the deflection devices, radiation can be coupled transversely into the connection points to cure the connecting material. It is also conceivable, for example, that the connecting material is applied to three connection points, whereby three deflection devices arranged substantially opposite one another are also provided. This can result in symmetry, whereby a certain self-focusing of the radiation coupled into the optical element can be achieved. The self-focusing can be substantially based on the shape of the optical surfaces, such as the top and bottom of the optical element. For example, when the radiation enters the optical element, a large number of total reflections on the optical surfaces and random scattering on the side surface of the optical element can result in increased intensity on the opposite side. The random scattering can depend for example on the roughness of the side surface. The roughness can cause a homogenization of the intensity of the radiation on the opposite side due to the statistics of the large number of scattered beams. As a result, uniform illumination can be achieved, which can be desirable for polymerization of the bonding material. A side surface of a rotationally symmetrical optical element, such as a lens, can be understood in particular as the edge cylinder of the optical element. In the case of a lens, the side surface can be at least substantially circular when viewed in the direction of useful light. The radiation path can, for example, pass through the center of the optical element, which can lead to higher intensities in the connection points.

According to an embodiment of the present disclosure, the deflecting device is at least partially designed to reflect the radiation for curing the joining material. It is conceivable, for example, that the deflecting device reflects radiation for curing the joining material in the direction of the joining material. For example, the deflecting device can comprise at least one reflective element. For example, a reflective element can be set up to at least partially reflect radiation. For example, a reflective element can be understood as a mirror surface or a tool with a mirror surface. For example, the reflective element can have a shape and/or orientation that can provide the highest possible light yield and/or the most uniform illumination possible in the connection point. For example, the reflective element can have a high reflectivity for the excitation radiation. For example, the deflecting device can be substantially designed as a reflector, such as for a spectral range of the electromagnetic spectrum, such as for a spectral range that matches the connecting material.

According to an embodiment of the present disclosure, the deflecting device comprises at least one reflective element in the form of a flat mirror surface. The flat mirror surface may have a straight contour on at least one side. Such mirror surfaces are easy to manufacture. For example, the flat mirror surface can each have a straight contour on four sides, for example by the flat mirror surface having a rectangular contour overall. Such a mirror surface can be relatively easy to manufacture.

According to an embodiment of the present disclosure, the deflecting device comprises at least one reflective element in the form of a concavely curved mirror surface. The curvature of the concavely curved mirror surface can be adapted to a contour of the optical element. As a result, a perpendicular incidence of light on the optical element, such as its side surface, can be achieved and the light yield can be improved.

According to an embodiment of the present disclosure, the deflecting device comprises at least one reflective element in the form of a convexly curved surface. As a result, at least partial expansion of the light beam of the radiation for curing the bonding material can be achieved.

According to an embodiment of the present disclosure, the deflecting device comprises at least one reflective element in the form of a reflective prism. The reflective prism can have a light entry surface, a light exit surface and a light deflection surface. For example, radiation for curing the bonding material can enter the reflective prism via the light entry surface, be reflected by the light deflection surface and exit the reflective prism via the light exit surface. The light exit surface can be flat or curved, for example concavely curved. A curvature, such as a concave curvature, leads to an increased light yield, while a straight surface is easier to produce. The light deflecting surface can have a reflective coating. Alternatively or additionally, total reflection can take place on the light deflecting surface. For this purpose, the light deflection surface can form an interface between the medium of the reflective prism with a higher refractive index, for example glass, and an adjacent medium with a lower refractive index, for example a gas such as air. By using a reflective prism as a reflective element, it can be achieved that the reflective element is both easy to manufacture and easy to handle, for example in the manufacture of a holding element or a tool element which comprises the reflective prism as part of a deflection device. Furthermore, the possibility of total reflection means that the radiation for curing the bonding material can be coupled into the bonding material with particularly low loss.

According to an embodiment of the present disclosure, the deflecting device comprises at least one light guide for deflecting the radiation for curing the bonding material. The light guide can be understood to be, for example, transparent fibers, for example glass fibers, tubes or cables that transport radiation. The light conduction can be achieved for example by reflection at the interface of the light guide by total internal reflection due to a lower refractive index of the medium surrounding the light guide, by mirroring the interface and/or by a suitable refractive gradient. Light guides can allow a particularly flexible deflection of the radiation for curing the bonding material. It is conceivable, for example, that the at least one light guide is at least partially curved. For example, the light guide is substantially bent at a 90° angle in order to couple radiation from a radiation source, which is arranged above or below the optical element and/or the holding element, transversely into the connection point, such as via a side surface of the optical element. One end of the light guide can, for example, be adjacent to a side surface of the optical element in order to couple radiation transversely through the optical element into a connection point. It is conceivable, for example, that the end of the light guide is adjacent to the side surface of the optical element on a side of the optical element opposite the connection point. Another end of the light guide can, for example, be adjacent to the radiation source. It is also conceivable that the holding element has a recess through which the light guide extends at least partially. In this way, one end of the light guide can, for example, adjoin a side surface of the optical element or be brought into contact with it. A light guide can, for example, be a rigid light guide, for example a light rod.

According to an embodiment of the present disclosure, the deflecting device for deflecting the radiation is detachably connected to the holding element. The deflecting device for deflecting the radiation for curing the connecting mechanism can, for example, be provided temporarily. The deflection device for deflecting the radiation for curing the connecting material can be provided for example for the duration of the irradiation for curing the connecting material. It is conceivable, for example, that the deflection device can be suitable for detachable connection to the retaining element. The deflecting device can be detachably connected to the retaining element for the duration of the irradiation of the connecting mechanism, for example. A reflective element, e.g. a mirror surface, can be temporarily inserted as a tool for the duration of the curing of the connecting material, such as opposite a connection point.

According to an embodiment of the present disclosure, the deflection device for deflecting the radiation is detachably connected to the holding element in that the deflection device is firmly connected to a tool element and the tool element is detachably connected to the holding element. This can simplify the temporary provision of the deflection device. The tool element can have the basic shape of a ring and comprise several deflection devices. For example, the number of deflection devices on the tool element can be a multiple of three. For example, the tool element can comprise three or six deflection devices. As already explained elsewhere, this can result in symmetry, so that a certain self-focusing of the radiation coupled into the optical element can be achieved. The holding element can have recesses to accommodate the deflection devices when the tool element is connected to the holding element. For example, the shape of the recesses can be complementary to the shape of the deflection devices. This can help make it easier to connect the tool element to the holding element.

According to an embodiment of the present disclosure, the tool element comprises two or more pin elements for fastening the tool element in complementary bores of the retaining element. In this way, a stationary and rotationally fixed positive attachment of the tool element to the holding element can be achieved. For example, the tool element can comprise three such pin elements. For example, the two or more pin elements can have play in the complementary bores of the retaining element in order to compensate for manufacturing tolerances.

According to an embodiment of the present disclosure, the tool element comprises at least one flat metallic surface for controlling the focusing of a light beam of the radiation for curing the bonding material. For example, the at least one planar metallic surface can have a diameter that is at least as large as a diameter of a light beam of the radiation for curing the bonding material. For example, the number of flat metallic surfaces can correspond to the number of deflection devices on the tool element, and the flat metallic surfaces can be arranged in the circumferential direction between the deflection devices. This can help make it possible to easily control the focusing of a light beam of the radiation for curing the bonding material by first rotating the tool element so that a stationary light beam strikes the at least one flat metallic surface. The focusing of the light beam can then be controlled, for example, via a contour sharpness of the projection of the light beam onto the at least one flat metallic surface. The tool element can then be rotated so that the light beam strikes the at least one deflection device.

According to an embodiment of the present disclosure, the deflecting device for deflecting the radiation is part of the holding element. The holding element can have the deflecting device for deflecting the radiation, for example permanently. It is conceivable, for example, that the deflecting device can be provided as a mirror surface on the holding element. The deflection device can, for example, be non-detachably connected to the holding element.

According to an embodiment of the present disclosure, the deflecting device for deflecting the radiation comprises a first and a second deflecting element. Here, the second deflecting element can be part of the holding element or part of the optical element. The first deflection element can be detachably connected to the holding element or be part of the holding element. Total internal reflection can occur at the second deflection element, especially if the second deflection element is part of the optical element. A first and a second deflector element can provide more options for guiding the radiation for curing the bonding material. The fact that the second deflection element is part of the optical element means that the second deflection element can be realized more easily, since, for example, the creation of a reflective surface on the optical element can be easier than on the holding element. Furthermore, the possibility of total reflection means that the radiation for curing the bonding material can be coupled into the bonding material with particularly low loss.

According to an embodiment of the disclosure, the holding element is a mount for holding the optical element. The mount can, for example, at least partially correspond to the outer shape of the optical element, in order to be able to accommodate it for example with a precise fit. Connecting the mount to the optical element via the connecting material can, for example, comprise positioning the optical element in the mount. The side surface of the optical element can, for example, form a gap with the inner surface of the mount into which the connecting material is inserted. When the optical element is aligned in the mount, the bonding material can, for example, be applied to a connection point through the gap. The gap can, for example, form an injection channel for the bonding material.

According to an embodiment of the disclosure, the retaining element is a socket for connecting to the optical element. Connecting the bushing to the optical element via the connecting material may, for example, comprise positioning the optical element with respect to the bushing.

According to an embodiment of the disclosure, the radiation for curing the joining material is at least partially scattered and/or diffracted. The scattering and/or diffraction can take place when the radiation is coupled into the bonding material. Alternatively or additionally, the scattering and/or diffraction can take place before the radiation is coupled into the joining material, for example when the radiation enters the optical element. For example, the optical element can have a rough surface for this purpose, whereby the light enters the optical element via the rough surface of the optical element and the incoming light is scattered by the rough surface. The rough surface of the optical element can for example be a side surface of the optical element. Alternatively or additionally, scattering and/or diffraction can take place in that at least one radiation-impermeable element with at least one recess is located between the deflection device and the bonding material in the path of a light beam of the radiation for curing the bonding material. Due to the opaque element, it is possible that at least part of the radiation of the light beam is absorbed before it is coupled into the bonding material. However, scattering can occur due to the recesses, for example due to surface roughness on the contours of the recesses, which can at least partially deflect the radiation for curing the bonding material before and/or during coupling into the bonding material. Alternatively or additionally, depending on the wavelength of the radiation and the size of the recesses, diffraction can also occur, as a result of which the radiation for curing the joining material can also be at least partially deflected before and/or during coupling into the joining material. The at least one radiation-impermeable element may, for example, be a radiation-impermeable element for fastening and/or holding the optical element, for example as part of the holding element. For example, the radiopaque element may be a retaining ring for the optical element, which has a plurality of recesses. In general, the light yield can be increased by scattering and/or diffracting the radiation to cure the bonding material.

According to an embodiment of the disclosure, the system further comprises a ball weight for positioning the optical element and the holding element relative to each other. The ball weight is used for example for positioning the optical element and a mount relative to each other. It is conceivable, for example, that the holding element is held stationary and the optical element is movable relative to the holding element with the aid of the ball weight. The ball weight can have at least one recess which is designed in such a way that the radiation for curing the bonding material passes through the recess of the ball weight to the deflection device for deflecting radiation for curing the bonding material. For example, the ball weight can be arranged above the optical element in such a way that the at least one recess of the ball weight is located above the at least one deflection device for deflecting the radiation for curing the bonding material. For example, the radiation can pass through the recess in the ball weight to the deflecting device. For example, the ball weight can have a number of recesses corresponding to the number of deflection devices so that, for example, a recess can be arranged above each deflection device. It is also conceivable that the ball weight can have at least one recess which is designed such that the deflection device for deflecting the radiation for curing the bonding material extends at least partially through the recess of the ball weight. For example, it is conceivable that the deflecting device comprises at least one light guide for deflecting radiation, which extends at least partially through a recess in the ball weight in order to direct radiation through the recess.

The system can also have a radiation source to provide the radiation for curing the bonding material. The radiation source is, for example, a UV radiation source, such as a UV condenser. It is also conceivable that a radiation source for radiation in a different spectral range is used. The bonding material is cured, for example, by rotating the optical assembly and/or the system. In this way, focused illumination can be used. It is also conceivable that the connecting material is cured using anular illumination. In this way, it can be possible to expose, for example cure, a relatively large number of connection points, such as all connection points, simultaneously.

The system can also comprise a connecting mount and/or a multi-leg mount, such as a tripod mount, for positioning the optical element and/or the holding element. It is conceivable, for example, that the optical element can be moved in the multi-leg mount with the aid of the ball weight and/or the holding element can be moved laterally on the connecting mount. The multi-leg mount can comprise a large number of support elements with support surfaces on which the optical element can rest. For example, it can be a tripod mount with three support elements. It is conceivable, for example, that the holding element, the optical element, the connection mount and/or the multi-leg mount can be rotated around the optical axis of the optical element on an air bearing during irradiation so that a number of connection points can be irradiated evenly.

The system can also include a measuring system for determining the positions of the holding element and the optical element in relation to each other. The measuring system can be used, for example, to determine the position of the optical element in the coordinate system of the holding element, which is designed as a mount.

The exemplary embodiments of the present disclosure described above in this description are also to be understood as disclosed in all combinations with each other. The individual features of each aspect may be combined with any or all of the features of the other aspects. Further embodiments and features of the disclosure will be explained in the following detailed description of some exemplary embodiments of the present disclosure in conjunction with the drawings.

In the following, embodiments and variants of the disclosure are explained in more detail with reference to the drawing. The aspects of the disclosure can be understood from the following detailed description in conjunction with the accompanying figures. The figures are schematic and simplified, showing only details to improve the understanding of the claims, while other details are omitted. The same reference numerals are used throughout for identical or corresponding parts. The individual features of each aspect may be combined with any or all of the features of the other aspects.

### BRIEF DESCRIPTION OF THE DRAWINGS

In the figures:

FIG. 1 shows a schematic representation of a system for connecting a lens mount to a lens according to the state of the art;

FIG. 2 shows the acceptance of the angle of incidence of the UV light depending on different lens geometries according to the state of the art;

FIG. 3 shows a schematic representation of an embodiment of a system according to the third aspect;

FIG. 4 shows a schematic representation of a further embodiment of a system according to the third aspect;

FIGS. 5A, 5B show a schematic representation of a further embodiment of a system according to the third aspect;

FIGS. 6A, 6B show a schematic top view of further embodiments of a system according to the third aspect;

FIGS. 7A, 7B show a schematic top view and perspective view of a further embodiment of a system according to the third aspect;

FIG. 8 shows a schematic representation of a further embodiment of a system according to the third aspect; and

FIG. 9 a schematic representation of a further embodiment of a system according to the third aspect.

### DETAILED DESCRIPTION

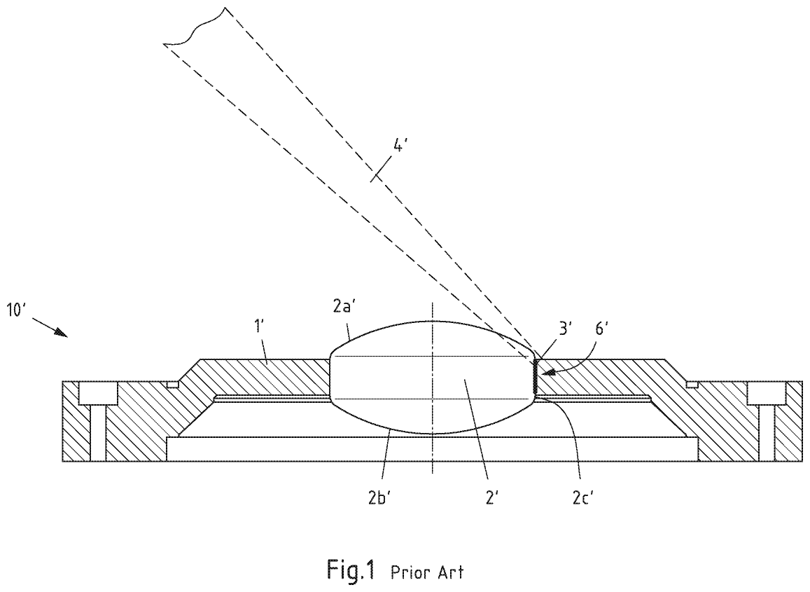

FIG. 1 shows a system 10′ known from the prior art for connecting a lens mount 1′ to a lens 2′. The lens 2′ is bonded into the lens mount 1′ at a bonding point 6′ with the aid of a UV-curable adhesive 3′, whereby UV light 4′ from a UV light source (not shown) is shone onto the bonding point 6′ to cure the adhesive 3′. After the lens 2′ has been positioned in the lens mount 1′, the UV light source is positioned in such a way that the UV light 4′ is coupled into the lens 2′ through the upper optical surface 2a′ of the lens 2′ and the focus of the UV light source is imaged on the side surface 2c′ of the lens 2′. Manual positioning of the UV light source can lead to deviations in position and angle.

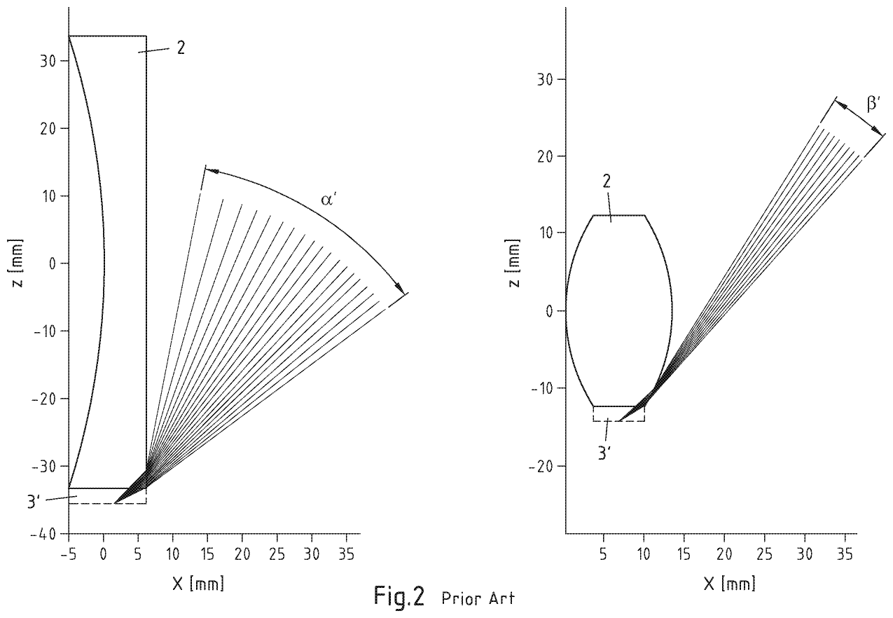

As shown in FIG. 2, different lens geometries accept different angles of incidence α′, β′ in order to couple the UV light 4′ into the adhesive 3′ at the bonding point 6′. For example, lenses with convex optical surfaces 2a, 2b can be considered to be particularly poorly suited for coupling light 4′ for adhesive curing. The process known from the prior art can limit the implementation of an optical design and can result in fluctuations in the strength of the adhesive 3′. This can result in position drifts of the optical element, which can jeopardize the actual function of the product.

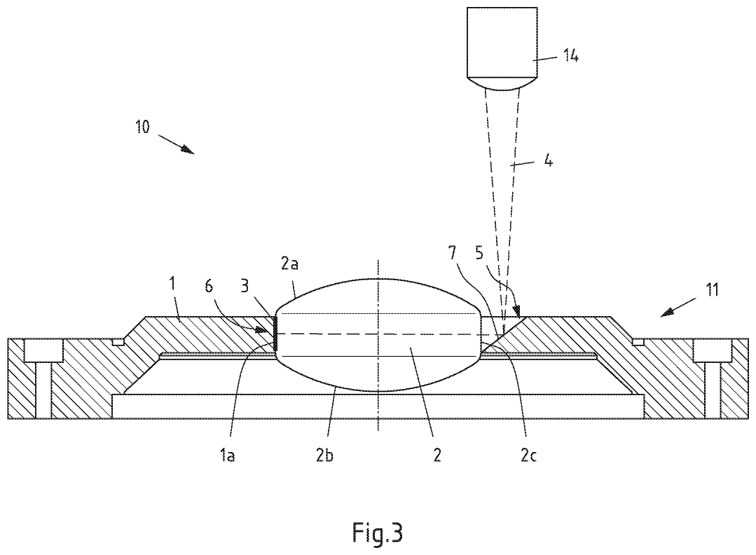

FIG. 3 shows an embodiment of a system 10 for connecting a holding element 1, which is formed as a mount 1a, to an optical element 2 via a connecting material 3 according to the present disclosure. The system 10 comprises the mount 1a and a transparent optical element 2, which is designed as a biconvex lens. The optical element 2 is accommodated in the mount 1a. The optical element 2 has two opposing convex optical surfaces 2a, 2b and a side surface 2c. To connect the optical element 2 to the holding element 3, a connecting material 3, in this case a UV-curable adhesive, is applied to a connection point 6 between the side surface 2c of the optical element 2 and the inner surface of the mount 1a. The bonding material 3 is irradiated with radiation 4 to cure the bonding material 3. The radiation 4 for curing the bonding material 3 is provided by the radiation source 14.

The radiation 4 from the radiation source 14 for curing the bonding material 3 is coupled into the optical element 2 via the side surface 2c of the optical element 2 via the deflection device 5 for deflecting the radiation 4, deflected transversely through the optical element 2 in the direction of the bonding material 3 and coupled into the bonding material 3 for curing the bonding material 3. The holding element 1 for connection to the optical element 2 via the connecting material 3 comprises the deflecting device 5 for deflecting radiation 4 for curing the connecting material 3. The deflecting device 5 is designed as a reflective element 7, for example as a mirror surface, which is part of the holding element 1. The deflecting device 5 is arranged at least substantially opposite the connection point 6 and is designed in such a way that radiation 4 incident on the deflecting device 5 is coupled into the connecting material 3 between the holding element 1 and the optical element 2 via the deflecting device 5 for curing the connecting material 3. It has been shown that more power can be provided by indirect irradiation, regardless of the shape of the optical element 2. For biconvex lenses for example, approximately 15 times the power can be made available with the same input power of the radiation source 14 compared to the connection method known from the prior art. The higher efficiency also enables a shorter exposure time.

The system 10 can be used to produce an optical assembly 11 for microlithography comprising the optical element 2, the holding element 1, which is connected to the optical element 2, and the deflection device 5, which is set up to deflect radiation 4 for curing the bonding material 3.

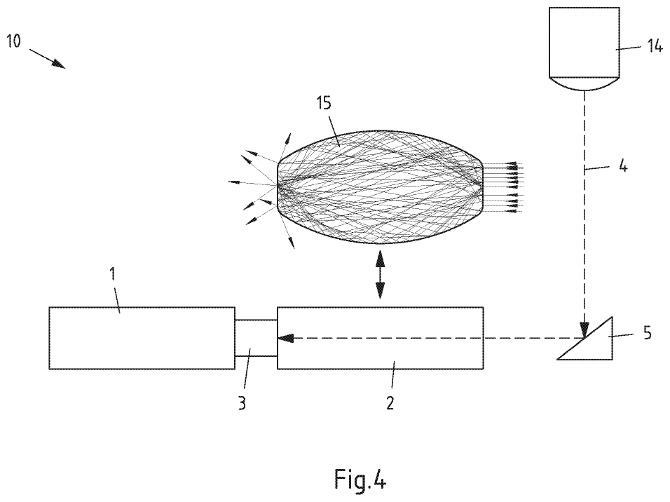

FIG. 4 shows a further embodiment of a system 10 for connecting a holding element 1 to an optical element 2 via a connecting material 3 according to the present disclosure. In addition to the transparent optical element 2 and a holding element 1 for connection to the optical element 2, the system 10 comprises a deflection device 5 for deflecting radiation 4 for curing the connecting material 3. The deflection device 5 is designed such that radiation 4 impinging on the deflection device 5 for curing the connecting material 3 is deflected transversely through the optical element 2 via the deflection device 5 and coupled into the connecting material 3 between the holding element 1 and the optical element 2. The optical element 2 acts as a light guide 15, resulting in total reflections on the optical surfaces in the optical element 2. This can create a focus on the opposite side of the optical element 2. The deflector 5 is only temporarily inserted into the system 10 as a tool for the duration of the irradiation of the connecting material 3. The deflector 5 can, for example, be detachably connected to the holding element 1 and removed again after irradiation of the bonding material 3. The bonding material 3 can be cured by rotating the system 10. Alternatively, it is conceivable that the curing of the joining material is carried out with anular illumination.

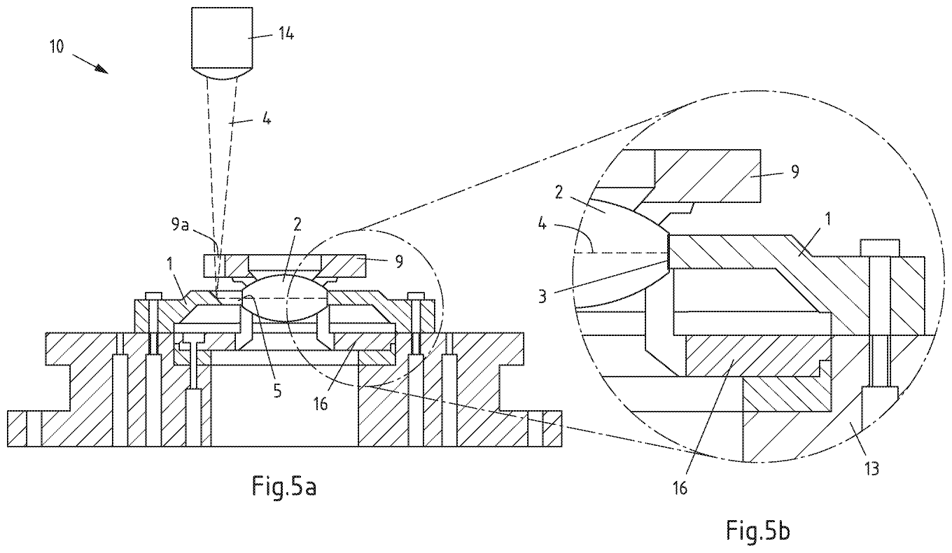

FIGS. 5A and 5B show a further embodiment of a system 10 for connecting a holding element 1 to an optical element 2 via a connecting material 3 according to the present disclosure. The system 10 comprises a holding element 1, which is designed as a mount 1a for holding the optical element 2. The optical element 2 is accommodated in the mount 1a. The side surface 2c of the optical element 2 forms a gap 12 with the inner surface of the mount 1a, into which the connecting material 3 is inserted. A deflection device 5 for deflecting radiation 4 for curing the bonding material 3 is arranged on the side of the optical element 2 substantially opposite the gap 12.

The position of the optical element 2 in the coordinate system of the mount 1a is determined via a measuring system (not shown). A connection mount 13 for positioning the holding element 1 and a multi-leg mount 16 for positioning the optical element 2 are also provided. The multi-leg mount 16 has support elements distributed around the circumference of the optical element 2 with support surfaces for mounting the optical element 2 in the mount 1a. A ball weight 9 is also provided for positioning the optical element 2 and the mount 1a relative to each other. With the aid of the ball weight 9, the optical element 2 can be moved in the multi-leg mount 16 and the holding element 1 can be laterally displaced on the connecting mount 13. When the optical element 2 is approximately aligned with the mount 1a, the connecting material 3 can be applied to the connection point 6 through the gap 12, which forms an injection channel.

After the position of the optical element 2 has been fine-tuned again, the radiation source 14, which is designed here as a UV condenser, provides radiation 4 for curing the bonding material 3. The ball weight 9 has a recess 9a, which is arranged above the deflection device 5 for deflecting radiation 4 for curing the bonding material 3, so that the radiation 4 from the radiation source 14 passes through the recess 9a of the ball weight 9 to the deflection device 5. The deflecting device 5, which is designed as a reflective element 7 for reflecting the radiation 4 for curing the bonding material 3, is arranged in such a way that the radiation 4 from the radiation source 14 passes transversely through the optical element 2 to the bonding point 6.

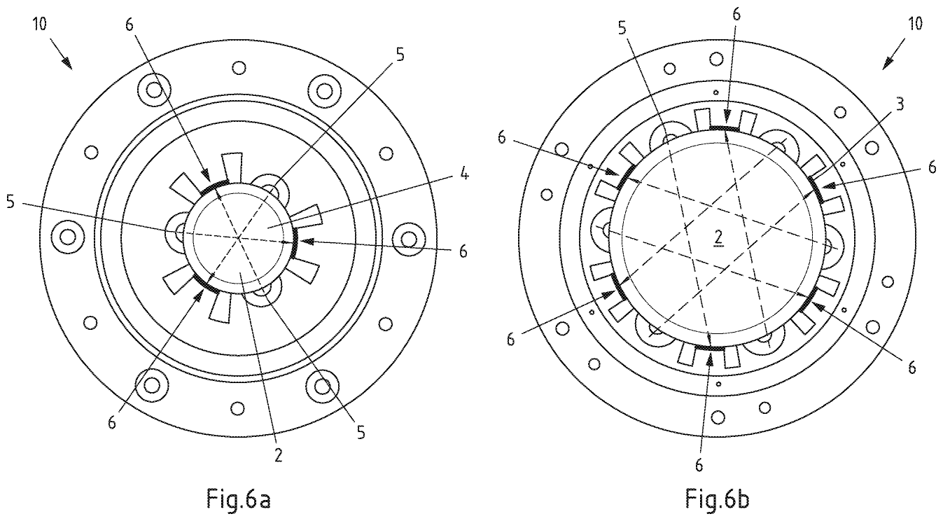

FIGS. 6A and 6B show further embodiments of systems 10 for connecting a holding element 1 to an optical element 2 via a connecting material 3. A plurality of connection points 6 are provided between the holding element 1 and the optical element 2, wherein a deflection device 5 for deflecting the radiation 4 for curing the bonding material 3 is arranged on an at least substantially opposite side of the optical element 2 at each of the connection points 6. In FIG. 6A, three deflection devices 5 are provided for deflecting radiation 4 in the direction of three respective opposite connection points 6. This results in symmetry, whereby a certain self-focusing of the coupled radiation 4 can be achieved. In FIG. 6B, six deflection devices 5 are provided for deflecting radiation 4 in the direction of six substantially opposite connection points 6. The optical element 2 can thus be connected to the mount 1a at several connection points 6 along the side surface 2c of the optical element 2. For example, UV-curable adhesive can be used as the bonding agent 3, which is irradiated for curing via UV radiation 4 from a UV radiation source 14.

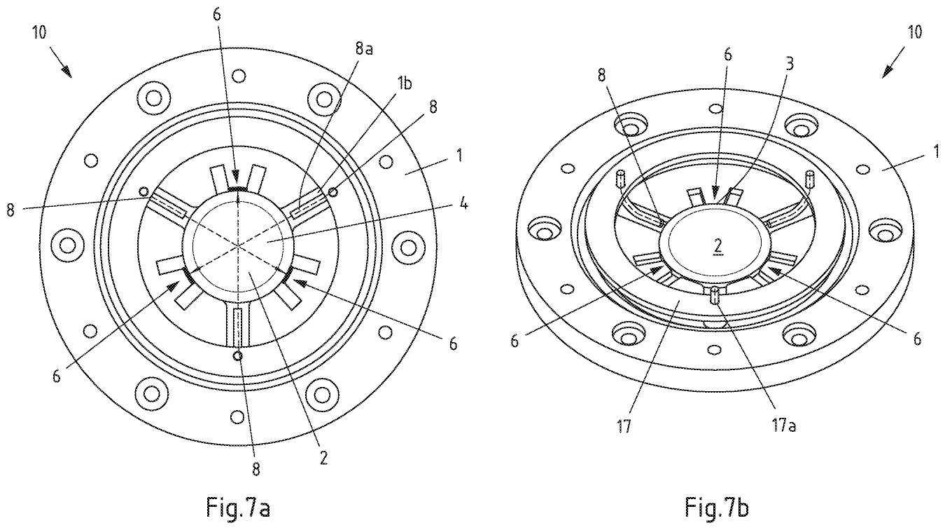

FIGS. 7A and 7B show a further example of a system 10 for connecting a holding element 1 to an optical element 2 via a connecting material 3. Three connection points 6 are provided between the holding element 1 and the optical element 2. One end 8a of an optical fiber 8 is arranged opposite each of the connection points 6. Using the light guides 8, radiation from a radiation source (not shown) is deflected at an angle of almost 90° and coupled into the optical element 2 opposite the respective connection point 6. The light guides 8 extend at least partially through recesses 1b in the retaining element 1. In this way, the ends 8a of the light guides 8 come close to the edge cylinder of the optical element 2. The light guides 8 also extend at least partially through a recess 17a of a mimic 17, which specifies the arrangement of the light guides 8.

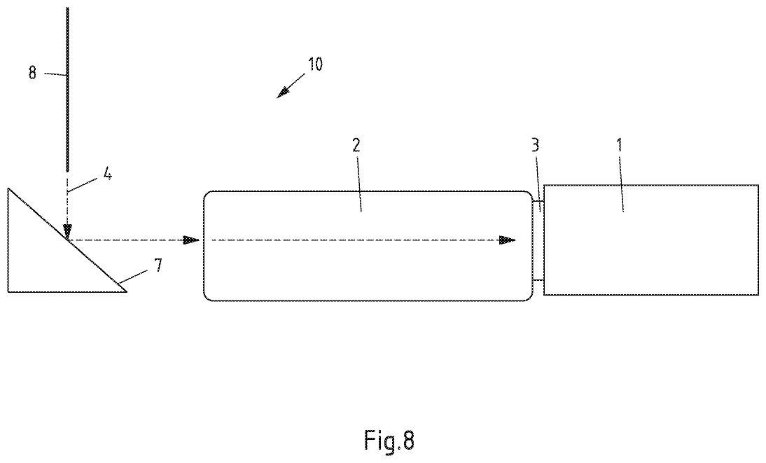

FIG. 8 shows a further embodiment of a system 10 for connecting a holding element 1, which is designed as a mount 1a, to a transparent optical element 2 via a connecting material 3 according to the present disclosure. To connect the optical element 2 to the holding element 3, the bonding material 3 is applied between the optical element 2 and the holding element 1. The radiation 4 for curing the bonding material 3 is provided by a radiation source (not shown). The radiation 4 is deflected via a light guide 8 onto a reflective element 7, which is designed for example as a mirror surface, and is coupled via the reflective element 7 via a side surface of the optical element 2 transversely into the optical element 2 and finally into the bonding material 3. The light guide 8 is, for example, a rigid light guide, for example a light rod. It is conceivable that a large number of light guides 8 and correspondingly arranged reflective elements 7 are provided in order to couple radiation into a corresponding number of connection points 6. Alternatively, it is conceivable, for example, that only one light guide 8 is provided, which is rotated in order to direct radiation onto a large number of reflective elements 7, which in turn deflect this radiation in the direction of the connection points 6.

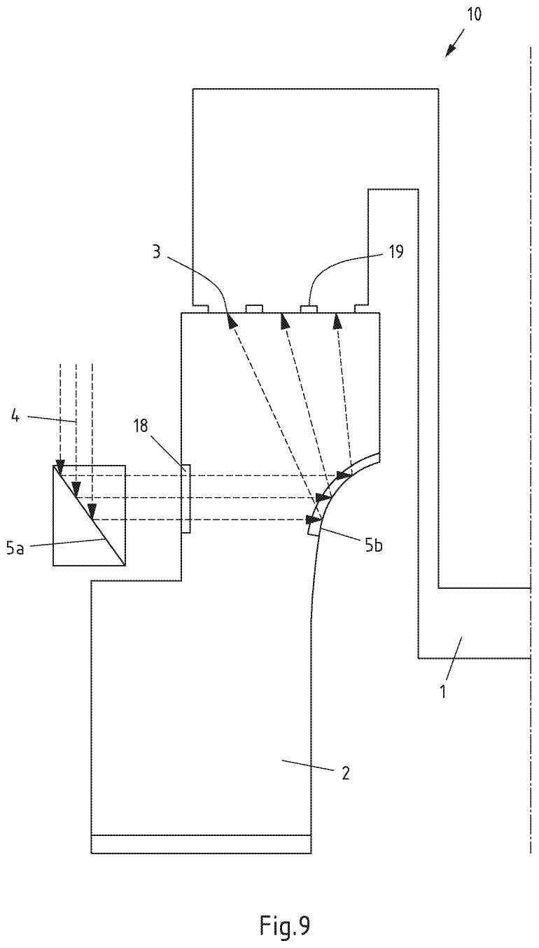

FIG. 9 shows a further example of a system 10 for connecting a retaining element 1 to an optical element 2 via a connecting material 3. The holding element 1 here is a mirror bushing 1 and the optical element 2 is a mirror 2. The mirror bushing 1 and the mirror 2, of which only sections are shown in each case, are connected to each other at several bonding points using a UV-curing adhesive as bonding material 3. The bonding points are located on the contact surfaces of the mirror 2 with the mirror bushing 1 between recesses 19 on the side of the mirror bushing 1. The bonding material 3 is irradiated with radiation 4 for curing, which is provided by a radiation source (not shown).

The radiation 4 from the radiation source for curing the bonding material 3 is coupled into the bonding material 3 via a deflecting device for deflecting the radiation 4. The deflection device comprises a first deflection element 5a and a second deflection element 5b. The first deflection element 5a is a reflection prism 5a, which reflects the incident radiation 4 at a light deflection surface via total internal reflection and thus deflects it for the first time. The light deflection surface is polished for this purpose and there is an air gap (not shown) behind the light deflection surface in the direction of the beam. After emerging from the reflection prism 5a, the radiation 4 strikes a polished surface 18 of the mirror 2, where it enters the substrate of the mirror 2.

The radiation 4 then hits the second deflection element 5b, which is designed here as a totally reflective convexly curved boundary surface 5b of the mirror 2 and thus forms part of the mirror 2. Since the convexly curved boundary surface 5b is also polished, and since there is air behind the convexly curved boundary surface 5b in the direction of the beam, total reflection also occurs here. This deflects the radiation 4 a second time so that it finally hits the bonding material 3, i.e. the UV-curing adhesive on the bonding surfaces. There, the radiation 4 is coupled into the bonding material 3, causing the adhesive to harden and the mirror bushing 1 to be bonded to the mirror 2.

In the embodiment example shown in FIG. 9, the radiation source (not shown) for generating the radiation 4 for curing the bonding material 3 can be an annular, i.e. a ring-shaped radiation source that temporarily surrounds the dome of the mirror 2 and the mirror bushing 1. Alternatively or additionally, the first deflecting element 5a can be annular.

The following embodiments are also disclosed:

A method of connecting a holding element to an optical element via a connecting material, comprising the steps of:
arranging the connecting material between the holding element and the optical element, and
curing of the connecting material, wherein the connecting material is irradiated with radiation for curing the connecting material, wherein the radiation for curing the connecting material is coupled into the connecting material via a deflecting device for deflecting the radiation.

Method according to embodiment 1, wherein the radiation for curing the bonding material is deflected transversely through the optical element in the direction of the bonding material via the deflection device for deflecting the radiation.

Method according to embodiment 1 or 2, wherein the optical element has at least one optical surface and one side surface, wherein the radiation for curing the bonding material is coupled into the optical element via the side surface of the optical element via the deflecting device for deflecting the radiation.

Method according to one of embodiments 1 to 3, wherein the bonding material is applied to at least one connection point between the holding element and the optical element, wherein the deflecting device for deflecting the radiation for curing the bonding material is arranged at least substantially opposite the at least one connection point between the holding element and the optical element.

Method according to embodiment 4, wherein the bonding material is applied to a plurality of connection points between the holding element and the optical element, wherein a deflection device for deflecting the radiation for curing the bonding material is arranged at least substantially opposite each of the connection points.

Method according to one of embodiments 1 to 5, wherein the deflecting device is at least partially designed to reflect the radiation for curing the bonding material, for example comprises at least one reflecting element.

Method according to one of embodiments 1 to 6, wherein the deflecting device comprises at least one light guide for deflecting the radiation for curing the bonding material.

Holding element for connection to an optical element via a connecting material, for example for use in a method according to one of embodiments 1 to 7, wherein the holding element comprises at least one deflecting device for deflecting radiation for curing the connecting material, wherein the deflecting device is designed such that radiation impinging on the deflecting device for curing the connecting material is coupled into the connecting material between the holding element and the optical element via the deflecting device.

Holding element according to embodiment 8, whereby the deflection device for deflecting the radiation is detachably connected to the holding element.

Holding element according to embodiment 8, wherein the deflecting device for deflecting the radiation is part of the holding element.

Holding element according to one of embodiments 8 to 10, wherein the holding element is a mount for receiving the optical element.

A system for connecting a holding element to an optical element via a connecting material, for example for carrying out a method according to any one of embodiments 1 to 7, comprising:
an optical element, and
a holding element, for example a mount, for connection to the optical element, for example a holding element according to one of embodiments 8 to 11, wherein the system comprises at least one deflecting device for deflecting radiation for curing the connecting material, wherein the deflecting device is designed such that radiation impinging on the deflecting device for curing the connecting material is coupled into the connecting material between the holding element and the optical element via the deflecting device.

The system according to embodiment 12, wherein the system further comprises:
a ball weight for positioning the optical element and the holding element, for example the mount, relative to one another, the ball weight having at least one recess which is designed such that the radiation for curing the bonding material passes through the recess of the ball weight to the deflecting device for deflecting radiation for curing the bonding material and/or that the deflecting device for deflecting the radiation for curing the bonding material extends at least partially through the recess of the ball weight.

An optical assembly for microlithography, for example produced by a method according to any one of embodiments 1 to 7, comprising:
an optical element, and
a holding element, for example a holding element according to one of embodiments 8 to 11, wherein the holding element is connected to the optical element, wherein the optical assembly comprises at least one deflection device for deflecting radiation for curing the connecting material, wherein the deflection device is designed such that radiation impinging on the deflection device for curing the connecting material is coupled into the connecting material between the holding element and the optical element via the deflection device.

What is claimed is:

1. A method of curing a connecting material disposed between an optical element and a holding element, the method comprising:
a) deflecting radiation from a deflecting element so that the deflected radiation passes transversely through the optical element; and
b) after the radiation passes transversely through the optical element, irradiating the connecting material with the radiation to cure the connecting material.

2. The method of claim 1, wherein:
the optical element comprises an optical surface and a side surface; and
during a), the deflected radiation is coupled into the optical element via the side surface.

3. The method of claim 1, wherein:
the bonding material provides a connection point between the holding element and the optical element; and
the deflecting device is at least substantially opposite the connection point.

4. The method of claim 1, wherein:
the bonding material provides a plurality of connection points; and
the deflection device is at least substantially opposite the connection points.

5. The method of claim 1, wherein the deflecting device is configured to at least partially reflect the radiation.

6. The method of claim 5, wherein the deflecting device comprises a reflecting element.

7. The method of claim 5, wherein:
the optical element comprises an optical surface and a side surface; and
during a), the deflected radiation is coupled into the optical element via the side surface.

8. The method of claim 1, wherein the deflecting device comprises a light guide configured to guide the deflected radiation.

9. The method of claim 1, wherein the optical element is rotationally symmetric.

10. The method of claim 1, wherein the optical element is an optical element of a microlithography system.

11. The method of claim 10, wherein:
the optical element comprises an optical surface and a side surface; and
during a), the deflected radiation is coupled into the optical element via the side surface.

12. A holding element configured to connect to an optical element via a connecting material, the holding element comprising:
a deflecting device comprising a deflecting element configured to deflect radiation so that, after deflecting from the deflecting device, the radiation passes transversely through the optical element and, after passing transversely through the optical element, the radiation irradiates and cures the connecting material.

13. The holding element of claim 12, wherein the deflecting device is detachably connected to the holding element.

14. The holding element of claim 12, wherein the deflecting device is part of the holding element.

15. The holding element of claim 12, wherein the holding element comprises a mount configured to hold the optical element.

16. A system, comprising:
an optical element;
a holding element;
a connecting material between the optical element and the holding element; and
a deflecting device configured to deflect radiation so that the deflected radiation passes through the optical element and irradiates and cures the connecting material.

17. The system of claim 16, further comprising a ball weight configured to position the optical and holding elements, wherein the ball weight has a recess configured so that the radiation passes through the recess before being deflected by the deflecting device.

18. The system of claim 16, further comprising a ball weight configured to position the optical and holding elements, wherein the ball weight has a recess, and the deflecting device is at least partially disposed in the recess.

19. The system of claim 16, wherein the system is a microlithography projection exposure system.

20. The system of claim 16, wherein the system is a microlithography projection system.
